(19) United States
(12) Patent Application Publication
(10) Pub. No.: US 2005/0253176 A1
(43) Pub. Date: Nov. 17, 2005

(54) Chip scale image sensor and method for fabricating the same

(76) Inventor: Sung Gyu Pyo, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/110,309

(22) Filed: Apr. 20, 2005

(30) Foreign Application Priority Data
Apr. 28, 2004 (KR) 10-2004-0029512

(51) Int. Cl. H01L 31/062

(52) U.S. Cl. 257/292

(57) ABSTRACT

Disclosed are a chip scale image sensor and its fabricating method. Such a chip scale image sensor includes a first substrate on which a peripheral circuit is formed, a second substrate which is stacked on the first substrate and on which a pixel array is formed, and global interconnections for electrically connecting the pixel array and the peripheral circuit. That is, since a pixel array and a peripheral circuit are separately formed and then are coupled to each other, there is no need to apply a repetitive fabricating process of forming multilayer metal interconnections to the pixel array. Thus, photosensitivity of the pixel array is not lowered, distances between a photodiode, a color filter and a micro lens can be minimized, and sensitivity of the image sensor can be still more improved due to a wide choice of light transmissive films.

### BACKGROUND OF THE INVENTION

1. Field of the invention

The present invention relates generally to an image sensor, and more particularly to an image sensor having a three-dimensional stacked structure and its fabricating method.

2. Description of the Prior Art

A CMOS image sensor has many advantages over the existing CCD image sensor. For example, its driving scheme is easier than that of the existing CCD image sensor, it can integrate a signal processing circuit on one chip and thus it possible to miniaturize a module of the image sensor, its cost of production can be lowered because an ordinary CMOS fabricating process can be applied to its formation, an so forth. A fabricating process of the CMOS image sensor is similar to that of a semiconductor device.

As shown in FIG. 1, a conventional CMOS image sensor may consist of a pixel region a to which an image is inputted and a peripheral circuit region b around the pixel region a, in which a signal processing circuit, a logic circuit or the like are formed. The pixel region a is formed with photodiodes 12. In the so-constructed conventional CMOS image sensor, a plurality of insulating interlayers 14 and interconnections 16 are stacked so as to provide multilayer interconnections, and a color filter 18 and a micro lens 20 are formed above the photodiode 12.

In such a structure of the conventional CMOS image sensor, diffused reflection of light may occur at interfaces between the insulating interlayer, and sensitivity of the image sensor may be lowered due to the refractions of light at interfaces between material films having different refraction indices from each other. Also, since vapor-disposition, etching and lithography steps are repeated during its fabricating process, the conventional CMOS image sensor has a problem in that there exist defects interrupting light transmission between the micro lens 20 and the photodiode 12 and thus defect pixels are generated.

Moreover, the conventional CMOS image sensor in which the pixel region a and the peripheral circuit region b are arranged in a plane has a difficulty in realizing System-on-Chip because the chip size must be increased in order to entrain various modules on one chip.

### SUMMARY OF THE INVENTION

Accordingly, the present invention has been made to solve the above-mentioned problems occurring in the prior art, and an object of the present invention is to provide an image sensor capable of enhancing sensitivity of light transmitted to photodiodes and its fabricating method.

A further object of the present invention is to provide an image sensor, which has enhanced sensitivity and can realize System-on-Chip without increasing its chip size, and its fabricating method.

In order to accomplish these objects, there is provided an image sensor and its fabricating method, in which a pixel array and a circuit region are separately formed and then are coupled to each other. Such an image sensor includes a first substrate formed with a peripheral circuit and a second substrate on which its pixel array is formed. The second substrate is preferably stacked on the first substrate. The pixel array and the peripheral circuits are electrically connected to each other by means of global interconnections.

To be concrete, the pixel array includes a driving transistor and a photodiode, and also includes a plurality of pixels arranged in a matrix form. A shade film having openings which expose the photodiode is formed on the pixels, and a color filter and a micro lens are formed above the photodiode. The peripheral circuit includes a plurality of multilayer metal interconnections, and the multilayer metal interconnections are electrically connected to the global interconnections and thus to the pixel array.

A fabricating method of an image sensor according to the present invention includes a step of forming a plurality of active and passive devices on a first substrate and a step of forming multilayer metal interconnections electrically connected to predetermined active and passive devices on the first substrate. The fabricating method also includes of forming a pixel array, in which a plurality of pixels including a photodiode and a transistor are arranged in a matrix form, on a second substrate. A color filter and a micro lens are formed above the photodiode.

Te first and second substrates are coupled to each other in a packaging step. That is, the first and second substrates can be stacked one above another to electrically connect the peripheral circuit and the pixel array to each other.

### BRIEF DESCRIPTION OF THE DRAWINGS

The above and other objects, features and advantages of the present invention will be more apparent from the following detailed description taken in conjunction with the accompanying drawings, in which:

FIG. 1 is a sectional view of a conventional image sensor;

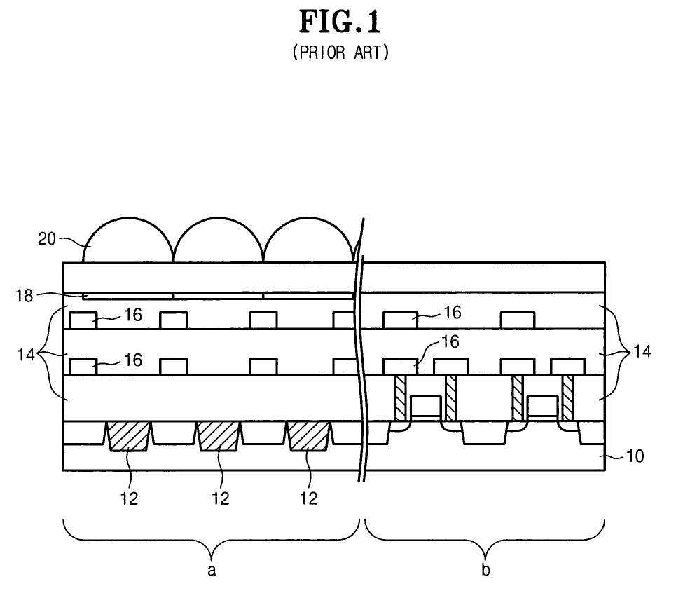

FIGS. 2a to 2c are process-by-process sectional views for explaining a method for fabricating a peripheral circuit of an image sensor in accordance with a preferred embodiment of the present invention;

FIGS. 3a to 3c are process-by-process sectional views for explaining a method for fabricating a pixel array of an image sensor in accordance with a preferred embodiment of the present invention; and

FIG. 4 is a process-by-process sectional view for explaining a method for fabricating a module of an image sensor in accordance with a preferred embodiment of the present invention.

### DETAILED DESCRIPTION OF THE PREFERRED EMBODIMENTS

Hereinafter, preferred embodiments of the present invention will be described with reference to the accompanying drawings. In the following description and drawings, the same reference numerals are used to designate the same or similar components, and so repetition of the description on the same or similar components will be omitted.

In an image sensor according to the present invention, a pixel array and a peripheral circuit are separately formed on different substrates and then are connected to each other.

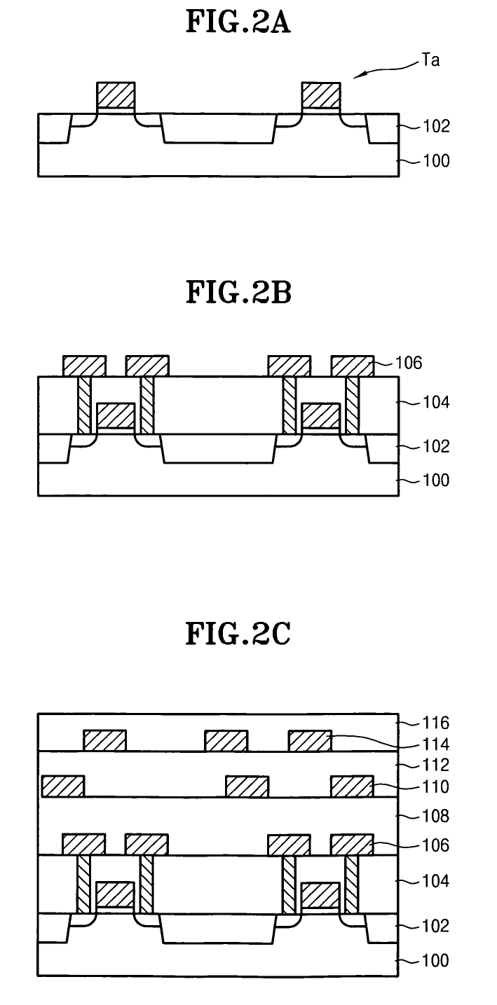

FIGS. 2a to 2c illustrate process-by-process sectional views showing a method for fabricating the peripheral circuit of the image sensor.

Referring to FIG. 2a, a device separating film 102 is formed on a first substrate 100 to define an active region, and a transistor Ta is formed the defined active region. Although not shown, various kinds of active and passive devices other than the transistor, such as a diode, a resistor, a capacitor and an inductor, can be formed on the first substrate 100 to realize a signal processing circuit and a logic circuit.

Referring to FIG. 2b, a first insulating interlayer 104 is formed on a front surface of the substrate on which the active and passive devices have been formed, and first interconnections 106 to be connected to the active and passive devices (transistor Ta in the drawing) are formed.

Referring to FIG. 2c, a second insulating interlayer 108 is formed on a front surface of the substrate on which the first interconnections 106 have been formed, and second interconnections 110 are formed on the second insulating interlayer 108. The second interconnections 110 penetrate the second insulating interlayer 108 to be connected to the predetermined first interconnections 106. In succession, a third insulating interlayer 112, third interconnections 114 and a passivation film 116 are sequentially formed. The above-mentioned interconnections may be stacked in plural layers to form multilayer metal interconnections according to the circuits formed on the first substrate. Although not shown, a pad for inputting/outputting external signals to/from the multilayer metal interconnections or for connecting a power source to the multilayer metal interconnections, such as an ordinary microchip may be formed, and global interconnections, which can penetrate the substrate to be electrically connected to the pixel array, may be also formed.

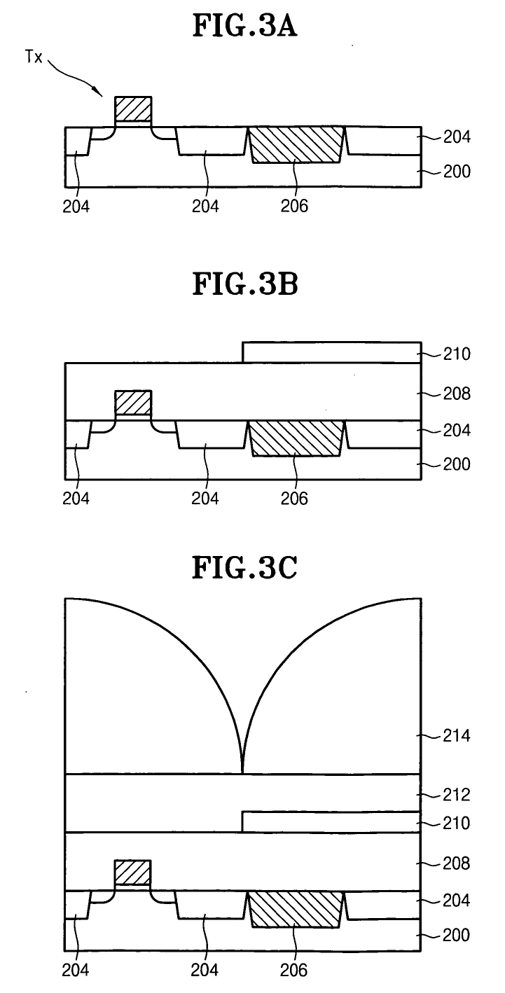

FIGS. 3a to 3c illustrate process-by-process sectional views showing a method for fabricating the pixel array of the image sensor.

Referring to FIG. 3a, a device separating film 204 is formed on a second substrate 200 to define a diode region and an active region. A photodiode 206 is formed in the diode region, and a driving transistor Tx for driving pixels is formed in the active region. The pixel array of a substrate level may be formed in the same way as a pixel array of an ordinary image sensor.

Referring to FIG. 3b, a first light transmissive film 208 having excellent light transmissiblilty to a visible ray is formed on a front surface of the substrate on which the photodiode 206 and the driving transistor Tx have been formed. The light transmissive film 208 may be formed of a material selected from materials capable of enhancing sensitivity of the image sensor. That is, in contrast with the conventional image sensor, only aspects of improving the sensitivity of the image sensor are taken into consideration without considering enhancement of characteristics of the peripheral circuits, so that a choice of material films can be widened. A color filter 210 is formed on the first light transmissive film 208.

Referring to FIG. 3c, a second light transmissive film 212 is formed on a front surface of the substrate on which the color filter 210 has been formed, and a micro lens 214 is formed on the second light transmissive film 212. According to the present invention, since only the interconnection layer for access to the driving transistor of the photodiode is required, the material films between the photodiode 206, the color filter 210 and the micro lens 214 can be minimized and a choice of materials is wide in terms of the improvement of photosensitivity.

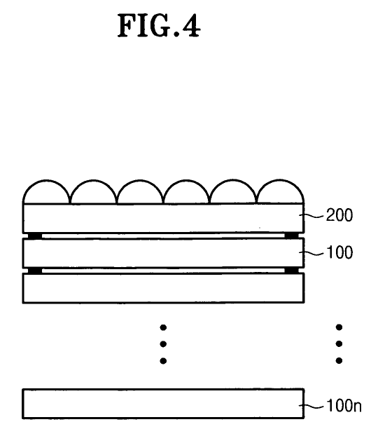

FIG. 4 illustrates a process-by-process sectional view for explaining a method for fabricating a module of an image sensor in accordance with a preferred embodiment of the present invention.

Referring to FIG. 4, the first and second substrates 100, 200 in which the peripheral circuit and the pixel array have been formed, respectively can be coupled to each other by applying a chip scale packaging method. At this time, a method for coupling the substrates to each other can be selected from well-known chip scale packaging methods. For example, as shown in the drawing, it is possible to couple the peripheral circuit and the pixel array to each other using bonding bumpers or using a wire bonding technique. The driving transistor on the second substrate in which the pixel array has been formed is connected to global interconnections formed through the substrate, and the global interconnections and the peripheral circuit are connected to each other by means of the bonding bumpers or the bonding wires. The image sensor according to the present invention can realize a multi-chip package by stacking a plurality of microchips as shown in the drawing because the pixel array is separately formed.

As described above, according to an image sensor of the present invention, a pixel array and a peripheral circuit are separately formed and then are coupled to each other, so that there is no need to apply a repetitive fabricating process of forming multilayer metal interconnections for the peripheral circuit to the pixel array. Thus, photosensitivity of the pixel array is not lowered, distances between a photodiode, a color filter and a micro lens can be minimized, and sensitivity of the image sensor can be still more improved due to a wide choice of materials of light transmissive films between the photodiode, the color filter and the micro lens.

Also, since the pixel array and the peripheral circuit can be stacked one above another and coupled to each other using a chip scale packaging technique, multi-chip packaging in which various circuits are coupled to each other can be realized, and an image sensor having multi-functionality without increase in device size can be provided.

Although preferred embodiments of the present invention have been described for illustrative purposes, those skilled in the art will appreciate that various modifications, additions and substitutions are possible, without departing from the scope and spirit of the invention as disclosed in the accompanying claims.

1. An image sensor comprising:
a first substrate on which a peripheral circuit of the image sensor is formed;
a second substrate which is stacked on the first substrate and on which a pixel array of the image sensor is formed; and
global interconnections for electrically connecting the pixel array and the peripheral circuit to each other.

2. The image sensor as claimed in claim 1, wherein the pixel array comprises a plurality of pixels including a driving transistor and a photodiode and being arranged in a matrix form, a color filter being formed above the photodiode, and a micro lens being formed above the color filter.

3. The image sensor as claimed in claim 1, the peripheral circuit includes a plurality of multilayer metal interconnections, and the multilayer metal interconnections are electrically connected to the global interconnections.

4. A method for fabricating an image sensor, the method comprising the steps of:
forming a plurality of active and passive devices on a first substrate;
forming multilayer metal interconnections electrically connected to the predetermined active and passive devices on the first substrate;
forming a pixel array, in which a plurality of pixels including a photodiode and a driving transistor are arranged in a matrix form, on a second substrate;
forming a color filter above the photodiode; and
forming a micro lens above the color filter.

5. The method as claimed in claim 4, further comprising the step of:
packaging of electrically connecting the pixel array and the peripheral circuit to each other by stacking the first and second substrates one above another.
